(19) United States
(12) Patent Application Publication
(10) Pub. No.: US 2026/0266882 A1
(43) Pub. Date: Sep. 10, 2026

(54) SYSTEMS AND METHODS FOR MONITORING AND DETECTING ELECTROSTATIC DISCHARGE (ESD) CONDITIONS AND EVENTS

(71) Applicant: IONA Tech LLC, Telluride, CO (US)

(72) Inventors: Daan STEVENSON, Telluride, CO (US); Jonathan TAPSON, Telluride, CO (US)

(73) Assignee: IONA Tech LLC, Telluride, CO (US)

(21) Appl. No.: 18/875,412

(22) PCT Filed: Jun. 16, 2023
(86) PCT No.: PCT/US23/68635

§ 371 Date: Dec. 16, 2024

Related U.S. Application Data
(60) Provisional application No. 63/352,944, filed on Jun. 16, 2022.

(51) Int. Cl. G01R 29/08

(52) U.S. Cl. CPC G01R 29/0814; G01R 29/0878

(57) ABSTRACT

Electrostatic discharge (ESD) mitigation devices, systems, and methods. In one embodiment, an electrostatic detection device includes motor with a motor shaft, a shutter mounted on the motor shaft for rotation, a printed circuit board (PCB) stack disposed between the motor and the shutter. The PCB stack includes a top layer including sensor electrodes, an inner layer including a rear shield, and a bottom layer including a motor electrical connection.

### CLAIM OF PRIORITY UNDER 35 U.S.C. § 119

The present Application for Patent is a National Stage Application of PCT/US2023/068635 entitled “SYSTEMS AND METHODS FOR MONITORING AND DETECTING ELECTROSTATIC DISCHARGE (ESD) CONDITIONS AND EVENTS” filed Jun. 16, 2023 which claims priority to Provisional Application No. 63/352,944 entitled “SYSTEMS AND METHODS FOR MONITORING AND DETECTING ELECTROSTATIC DISCHARGE (ESD) CONDITIONS AND EVENTS” filed Jun. 16, 2022, and assigned to the assignee hereof and hereby expressly incorporated by reference herein.

### FIELD OF THE DISCLOSURE

The present disclosure relates generally to a system for electrostatic discharge (ESD) protection. In particular, but not by way of limitation, the present disclosure relates to systems, methods and apparatus for a network of wearable or mobile or stationary electronic devices that monitor user electrostatic charge and raise alarms both on the device and/or on a connected network if the user potential exceeds a pre-set threshold, or if there are measured ESD events that exceed a threshold in number or size or both.

### DESCRIPTION OF RELATED ART

Electrostatic discharge occurs when an object or person containing an excess of electrostatic charge comes into contact with another conducting object or person. As two bodies with differing voltages approach, the electric field increases with the inverse of the decreasing distance between them, until the dielectric breakdown of the intervening air is exceeded. At this point the air is transformed to a conducting plasma, allowing a sudden transfer of electrical charge between the bodies.

If the interaction occurs between a person and an electronic device, the inrush of current may damage any sensitive electronics present on the device. If the differential voltage is sufficient to generate an electric spark, it might ignite any proximate flammable or combustible substances. Companies involved in electronics development and manufacturing must pay close attention to static charge mitigation in order to maintain product quality and reliability. In factories or warehouses where flammable or explosive chemicals are present, advancements in ESD mitigation stand to greatly improve workplace safety.

Conventional ESD mitigation products rely on a direct electrical connection between the user and Earth ground to carry away excess charge, such as by a tethered conducting wrist strap or grounding footwear and floor mats. Alternatively, cleanroom installations with climate control or air ionizers can reduce the probability for electrostatic discharges by accelerating the natural dissipation of excess charge from bodies to the environment. These approaches can be effective to mitigate ESD hazards, but rely heavily on user compliance and generally lack any feedback or data collection.

### SUMMARY OF THE DISCLOSURE

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

Some embodiments of the disclosure may be characterized as an electrostatic mitigation device including a motor including a motor shaft, a shutter mounted on the motor shaft for rotation; and a printed circuit board (PCB) stack disposed between the motor and the shutter. The PCB stack includes a top layer including sensor electrodes, an inner layer including a rear shield, and a bottom layer including a motor electrical connection.

Other embodiments of the disclosure may be characterized as an electrostatic detection device, including sensor electrodes configured to measure electric field, a shutter configured to alternately shield and expose the sensor electrodes to the electric field to generate a sensor signal, and a processor configured to demodulate the sensor signal to generate a demodulated sensor signal, and in response to determining the demodulated sensor signal exceeds a threshold, to generate an audio or visual alarm on the electrostatic detection device indicating a risk of an electrostatic discharge (ESD) event.

Other embodiments of the disclosure may also be characterized as a system for mitigating electrostatic discharge (ESD) events in a facility. The system includes a plurality of electrostatic detection devices attached to objects in the facility, each electrostatic detection device configured to measure a local surface charge of one or more objects in the facility, to determine an electrostatic potential of the one or more objects in the facility, and to transmit data of the electrostatic potential of the one or more objects in the facility. The system also includes one or more hubs disposed in the facility configured to forward the data of the electrostatic potential of the one or more objects in the facility. The system further includes a remote computing device configured to receive the data of the electrostatic potential of the one or more objects in the facility, and to generate a map of the facility that displays locations in the facility having or that have had an electrostatic potential exceeding a risk threshold of an ESD event.

Other embodiments of the disclosure may be characterized as a method including providing a motor including a motor shaft, mounting a shutter on the motor shaft for rotation, and disposing a printed circuit board (PCB) stack between the motor and the shutter, the PCB stack including a top layer including sensor electrodes, an inner layer including a rear shield, and a bottom layer including a motor electrical connection.

Other embodiments of the disclosure may be characterized as a method of mitigating electrostatic discharge (ESD) events with an electrostatic detection device. The method includes measuring an electric field with sensor electrodes, generating a sensor signal with a shutter that alternately shields and exposes the sensor electrodes to the electric field, and demodulating the sensor signal to give a demodulated sensor signal. The method further includes, in response to determining the demodulated sensor signal exceeds a threshold, generating an audio or visual alarm on the electrostatic detection device indicating a risk of an electrostatic discharge (ESD) event.

Other embodiments of the disclosure can be characterized as a method of mitigating electrostatic discharge (ESD) events in a facility. The method includes measuring a local surface charge of one or more objects in the facility with electrostatic detection devices, determining an electrostatic potential of the one or more objects in the facility based on the local surface charge, and generating, with a remote computing device, a map of the facility that displays locations in the facility having an electrostatic potential exceeding a risk threshold of an ESD event.

### BRIEF DESCRIPTION OF THE DRAWINGS

Various objects and advantages and a more complete understanding of the present disclosure are apparent and more readily appreciated by referring to the following detailed description and to the appended claims when taken in conjunction with the accompanying drawings:

FIG. 1 shows a user wearing an embodiment of a wireless electrostatic detection device.

FIG. 2 shows an arrangement of a stationary or fixed sensor device mounted on a workbench.

FIG. 3 shows details of a device such as the one shown in FIG. 2 or FIG. 1.

FIG. 4 shows an exploded view of the sensor structure.

FIG. 5 shows three layers of an electric field sensor fabricated in PCB.

FIG. 6 shows an embodiment of a miniaturized electric field mill with bias and sensing electronics.

FIG. 7 shows a data network that can support and enable the sensing devices.

FIG. 8 shows the presentation of data for the above-mentioned sensors for a remote user in the form of a dashboard of charts and tabular data on a computer screen, as served in the form of a web page by a cloud server.

FIG. 9 shows an exemplary chart of body potential as deduced by the recorded electric field measurement from a wearable device of the type described herein.

FIG. 10 shows an example of a representation of a floor map of a manufacturing facility.

FIG. 11 illustrates a method of manufacturing an electrostatic detection device in one embodiment.

FIG. 12 illustrates a method of mitigating electrostatic discharge (ESD) events with an electrostatic detection device in one embodiment.

FIG. 13 illustrates a method of estimating an object or user body potential in one embodiment.

FIG. 14 illustrates a method of mitigating electrostatic discharge (ESD) events in a facility in one embodiment.

FIG. 15 shows a block diagram depicting physical components that may be utilized to realize controllers according to an exemplary embodiment.

### DETAILED DESCRIPTION

The wireless electrostatic detection device and method described herein provides newfound traceability in the prevention of electrostatic shocks, yielding an increase in safety and productivity.

The word “exemplary” is used herein to mean “serving as an example, instance, or illustration.” Any embodiment described herein as “exemplary” is not necessarily to be construed as preferred or advantageous over other embodiments.

Preliminary note: the flowcharts and block diagrams in the following Figures illustrate the architecture, functionality, and operation of possible implementations of systems, methods and computer program products according to various embodiments of the present disclosure. In this regard, some blocks in these flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items, and may be abbreviated as “/”.

It will be understood that when an element or layer is referred to as being “on,” “connected to,” “coupled to,” or “adjacent to” another element or layer, it can be directly on, connected, coupled, or adjacent to the other element or layer, or intervening elements or layers may be present. In contrast, when an element is referred to as being “directly on,” “directly connected to,” “directly coupled to,” or “immediately adjacent to” another element or layer, there are no intervening elements or layers present.

Embodiments of the disclosure are described herein with reference to cross-section illustrations that are schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of the disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Embodiments of the present disclosure feature a wireless electrostatic detection device that can be worn by the user without a tethered reference to ground, or placed in a stationary position such as at a workbench, and which can alert the user and colleagues when a threshold of ESD danger is being exceeded. Typically, the device will measure the local electric field, which is an accurate proxy for the user's electrostatic potential, and if the measurement exceeds a threshold an alarm can be generated. If the alarm is audible, as created by a buzzer, the user is then made aware that any contact with sensitive electronics should be avoided until the user has grounded themself and thereby brought their potential into a safe range.

The device can also remotely measure sudden changes in user potential which would indicate that a discharge event has taken place, and the size of the change in the potential can indicate the magnitude of the discharge. This data can be used to identify potential damage to an electrical device or asset on which work was being performed, and also indicates a failure of ESD mitigation in the facility, such as inadequate grounding of conductive flooring. A person with the responsibility to manage ESD mitigation can thereby generate an ESD history for electronic assets, and use the data to improve systems and practices for ESD mitigation (e.g., identifying inadequate grounding of conductive flooring).

The herein disclosed device(s) can be connected using a wireless digital network such as Wi-Fi, Bluetooth Low Energy, LoRa, z-wave, 5G or any similar or future wireless network system as may be appropriate to communicate the device(s) data to the cloud and/or Internet. In the case of stationary sensors, cabled networks such as Ethernet may be used in place of or in parallel to wireless networks. Each device may communicate with one or more local hubs, which can help to aggregate, process and forward the data from the devices, and may themselves be equipped to create alarms if necessary. These hubs can take the form of a single board computer, a mobile computing device, or any other type of computing device.

Both the devices and the hubs may be equipped with auxiliary sensors which may help to improve the quality of the human electrical potential measurement (such as, but not limited to, accelerometers or inertial measurement units to detect the orientation of the device in space, or proximity sensors to determine the position of local objects). Both the devices and the hubs may additionally have environmental sensors which detect variables such as humidity, temperature and air ion density, as it is commonplace for these variables to be controlled to improve ESD mitigation in an indoor facility. In this way the devices and hubs act as local sensors for measuring the quality of ESD mitigation efforts.

Generally, the electrostatic potential difference of a body from a ground reference is the best determinant of a propensity for ESD events. Measuring this electrostatic potential, however, typically involves a physical tether from the body to Earth ground. Instead, an electric field sensor may be used in a wearable and mobile fashion to deduce user or worker electrical potential without encumbering tethers. That is, the sensor device described herein provides a technical benefit of accurately estimating a user's body voltage without a wired connection to ground. To do so, the sensor device measures the electric field on the surface of a conducting body which is a direct measure of the local surface charge density at the measurement location. Here, the local surface charge density may be at the local surface of the user's skin or covering garments.

The sensor device described herein also provides a technical benefit of accurately extrapolating the electric field measurement to a body voltage or potential which can be compared to a voltage safety threshold for purposes of ESD mitigation. The extrapolation from local electric field measurement to body voltage may depend on the local surface having electrically conductive properties (e.g., bare human skin or electrically dissipative clothing material such as an ESD-rated smock). The housing of the device may comprise electrically dissipative material to ensure that little local charge is maintained on the device housing.

Extrapolating the local surface charge density to the whole body geometry yields the total body electrostatic charge. Dividing the total charge by the body self-capacitance then yields the user's electrostatic potential. A body factor can be empirically-derived to convert the local E-field measurement to the potential or voltage, and can be adjusted based on body geometry deviances. Nearby conducting shapes and charges can affect the relationship between field measurement and body voltage, but in general the local electric field measurement on a user's body is an accurate proxy for that user's electrostatic potential, and thereby their propensity for ESD events.

Measuring local electric fields via wearable devices has proven challenging, but this disclosure overcomes those challenges via an electric field mill design of a miniaturized form factor, which allows it to be implemented in a wearable device. The electric field mill described herein is insensitive to absorption of ionic air particles. Moreover, even with its small form factor, it exhibits sufficient accuracy and temporal resolution to identify electrostatic discharge events caused by potential differences of less than 100V, far lower than is physically perceptible by the user. The novel field mill design provides data at a resolution below 10 V/m and at greater than 1.2 kHz frequency. By assessing the rate of change of the electric field, the sensor can discern between an electrostatic change due to triboelectric effects and the more rapid loss of electrostatic charge from the body that is the result of a possibly damaging electrostatic discharge (ESD) to a separate object such as an electronic workpiece. This is possible in both the wearable sensor and the stationary sensor aimed at the person involved in the ESD event. Other contactless ESD detection devices in the prior art rely on an amplified signal from an antenna that receives an electromagnetic signature from the electric spark inherent to the ESD event, and therefore has much lower accuracy in determining the size of the discharge. In different embodiments of this disclosure, an electric field sensor based on oscillating or vibrating electrodes may be used, or any other that is sufficiently sensitive and agnostic to ionic interference, and has a sufficient sample rate.

Other solid state electric field sensors based on Field Effect Transistors (FETs) are sufficiently small, but obtain significant irreversible offsets when coming in contact with ionic air particles, which are generally found in high densities in ESD rated facilities. Shielding the sensor from airborne electrically charged contaminants is not an option because if the shield is electrically conductive to a reference ground plane it forms an effective Faraday cage that obscures the sensor's signal, while if the shield is electrically floating or has insulating properties it will obtain a net charge from ionically charged particles, causing incorrect readings at the sensor that do not represent the actual electric field in space.

To solve the problem of contamination by ionic air particles faced by FET based solid state electric field sensors, a conductive mechanical shutter can be used that periodically interrupts or shields the sensor from the external field. This means that the sensor can alternately measure the external field, and a baseline internal field measurement that includes the signal from external charges. Both electrodes experience the same interaction from airborne ionic particles and interference from this signal is effectively nullified. In an electric field mill, a shutter with radial sectors is rotated by a motor so that the sectors alternately cover and expose sensor electrodes. Alternatively, a vibrating conductive lever or reed can be used to shield and expose the sensor. The field mill is favored in applications where high sensitivity is required, as it allows for two or more differential sensor plates to be used, allows for variable size and geometry of sensor plates, and allows for the provision of extra electrodes which may be used to null or calibrate the sensor in different applications.

For these reasons, the electric field mill is highly desirable where high accuracy in DC field measurement is intended. However, it has not previously been used on wearable or miniaturized equipment, because the sensor is very difficult to miniaturize. There are a number of reasons for this;
1. The shutter is preferably rotated by an electric motor or similar actuator;
2. The position of the shutter should be known at all times to successfully demodulate the sensor signal. Existing field mills use an extra mechanical plate (known in the art as a “signal star”) mounted on the motor shaft to accomplish this;
3. The rotating shutter should be kept at a fixed voltage (usually ground). Existing field mills use a sliding electrical contact, usually in the form of a carbon brush, between the sensor circuit and the rotating motor shaft;
4. The fixed part of the sensor consists of a stack of electrodes, including the sensor electrodes, a back electrode to provide a ground or calibration signal, and potentially a further electrode either in front or behind of the sensor electrodes to provide a nulling signal; and
5. All of the above elements should be insulated from one another, with the insulation being a potential source of ionic charge contamination, and the geometry of the arrangement therefore being generally intricate. This is exacerbated by the need for these plates to be precisely aligned both along the motor axis and angularly with respect to the motor shaft, as well as being precisely parallel with each other and perpendicular to the motor shaft.

In the current disclosure, a number of novel steps have been made that allow for a miniaturized and simplified construction of the electric field mill, while improving its accuracy and making it suitable for a wearable device.

In an embodiment, a small motor (e.g., 8 mm in length and 4 mm in diameter) is used to spin the shutter, having a shaft running on a solid metal bushing so that a conductive link is provided from the motor shell to the moving shaft. While previous disclosures suggest that the shaft-to-bearing connection is insufficiently reliable to be used in the shutter connection (see reason 1 above), this disclosure finds that if a solid metal bushing is used, the connectivity is equivalent to the common slip-ring connection, and is sufficient for the noise to be negligible. This also simplifies the connection of the motor and hence shutter to the main circuit, as it can be soldered directly to the sensor as described below. The functions of the shutter and a “signal star” (see reason 2 above) are combined by extending a diameter of the shutter so that it can pass through an optical interrupter (photodetector) beyond the edge of the sensor.

The problem of the mounting and alignment (see reason 5 above) has been solved by manufacturing the entire stack of electrodes as a single piece of multilayer printed circuit board (PCB). A single board may contain conductive features on multiple layers and 4-, 6- and 8-layer boards are now commonplace. The features on these layers are manufactured with very precise tolerances. A PCB of this type can be a lamination of multiple layers of copper-coated fiberglass sheet. The copper layers are photo-masked and chemically etched with great precision to ensure the integrity of the circuits-alignment resolution of 50 μm is commonplace. The PCB materials are designed to ensure high mechanical and electrical stability in harsh environments.

The use of PCB to create the field mill structure has numerous significant advantages. For one, the electrodes connect directly to the circuit features such as amplifiers and the motor, without any need for wires, which can create an electrical noise and reliability hazard. Second, the alignment of all electrodes and the motor is permanently fixed and ensured by the PCB structure. Third, the only surface of the entire sensor stack which is exposed to air, and hence contamination, is the sense electrode surface, which, as mentioned above, is difficult to cover anyway. Similarly, the insulating material between the stack layers is internally contained in the PCB with no exposure to contaminants. Finally, the spacing between the conductive layers is very small-the whole PCB thickness can be a millimeter or less-so that the entire stack takes up less space than a single layer in previous designs.

The use of a PCB for the sensor allows the mounting of a multi-function microprocessor close to the electrodes. This enables a number of features which contribute to the improved accuracy of the sensor over existing designs. The first is that the speed of the motor can be precisely controlled, using the signal from the shutter position photodetector as an input, and a motor drive voltage controlled by a pulse-width modulated (PWM) power transistor as an output. Precise speed control has two advantages. The first is that the field mill signal for a given field strength is affected by shutter rotational speed, so controlling the speed reduces measurement inaccuracy. The second and more important feature is that this sensor is designed for indoor use, which is quite unusual for field mills, which are normally used for atmospheric research outdoors. In an indoors environment there are strong AC electric fields at the frequency of the building electrical utility supply (60 Hz in the US), and these fields cause noise and inaccuracy in DC field measurements. A noise component at a specific frequency, and its frequency integer multiples, can be nulled out by demodulating the signal at that frequency. This has been applied in this case by using the speed control of the microprocessor to rotate the shutter so that the shutter blade pass frequency is an integer multiple of 60 Hz (for example, 30 Hz or 1800 rpm). The signal produced from the electrodes is then synchronously demodulated at this frequency, thereby nulling out the effect of any 60 Hz AC fields on the DC field measurement. Moreover, due to the small size of the field mill motor and small rotational inertia of the shutter (e.g., shutter radius between 10 to 20 millimeters), higher rotation speeds can be achieved with lower current draw than in conventional field mills of greater size.

Previously, synchronous demodulation of the field mill signal with respect to the shutter position in EFMs has been carried out by electronic hardware demodulation circuits. Demodulating in software gives a great deal more control and hence accuracy. For example, there is usually a small but non-zero phase error between the shutter signal and the electrode signal, caused by mechanical misalignments, and electronic phase shifts in the analog amplification chain. Using the present system, this phase error can be measured (calibrated) and compensated out in software demodulation.

When the electric field sensor is used in a wearable device mounted on the body, and there is an insulating article of clothing between the device and the user's skin, accuracy may be improved if the sensor has electrically conducting connection to the wearer's body. This places the sensor's reference ground plane at the same potential as the wearer, and prevents the device from acquiring an electrostatic potential that differs from the user's. It can be shown mathematically that the electric field at the wearer's body surface is perpendicular to the local body surface, and linearly related to the charge density on the wearer's surface (skin or conductive clothing) at that location. The sensor should be placed and aligned so as to be most sensitive to the field perpendicular to the skin or clothing surface. The surface charge density and therefore the electric field are indications of the likelihood of charge transfer to external objects, and alarm thresholds can be set accordingly.

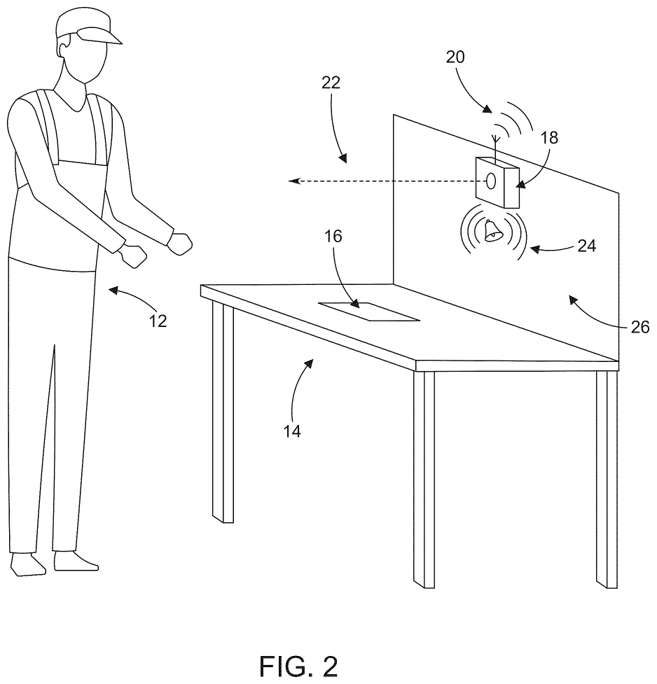

When the device is fixed, for example to the back of a bench as shown in FIG. 2, the device should have an electrical connection to a ground point, and the sensor should be arranged so as to measure the field from this reference ground in the direction from which a worker would most likely approach the bench. It may also be necessary to shield the sensor or arrange ground planes so that inappropriate fields (for example, from beyond the back of the bench) do not affect the sensor. If set up correctly, the surface charge on a worker approaching the bench or work area will create a non-zero electric field that can be measured by the sensor, and alarm thresholds can be set accordingly.

In either the wearable or fixed case, it may be possible to use a floating or vector electric field sensor (see e.g., U.S. Pat. No. 8,536,879B2, “A miniaturized space-potential DC electric field meter”, A. R. Johnston and Harold Kirkham, IEEE Transactions on Power Delivery, 1989, Volume 4, Pages 1253-1261.), in which case the field vector of interest can be measured. In the case of a wearable device, this vector is the field in the direction perpendicular to the wearer's skin, at the point the device is worn. In the case of a fixed sensor, the vector of interest would be in the direction from which a worker would most likely approach the bench or work area.

A distance or proximity sensor may be integrated into the device in order to improve the conversion of the electric field sensor output into a measurement of body potential. Conversion of electric field strength to a voltage is common in the design of non-contact surface voltmeters, but this is usually performed at a fixed and known distance, which may be set mechanically or by means of a visual indicator such as crossed laser beams. The herein disclosed proximity sensor would measure, in the case of a stationary (workbench mounted) device, the distance from the electric field sensor to the user/worker. This extra information helps to improve the calculation of body potential from the measured electric field. In the wearable sensor case, a proximity sensor can be used to identify when there are locally proximate charged objects, and can also help to identify situations where the electric field sensor has been occluded (say for example by clothing) and identify this malfunction to the user.

Both the wearable and the fixed sensors may be unable to distinguish between the case where a person is electrostatically charged, and the case where there is an electrostatically charged object in close proximity (for example, the person is carrying a charged object such as an insulated tray; or a charged tool such as a pair of pliers with insulated handles is brought close to the workbench). However, in both cases it is appropriate to generate an alarm since the charged object constitutes an ESD hazard.

It is possible that a mobile version of the device may be placed on a mobile but inanimate platform for the purposes of generating alarms if that platform exceeds ESD thresholds. For example, in many facilities, electronic circuits in production are moved from place to place on wheeled trolleys or belt conveyors, both of which generate electrostatic charge if they are not properly grounded. Placing a mobile device on such a conveyance or on the conveyed package would help to identify when its grounding is failing or has failed, thereby avoiding ESD damage to the conveyed circuits.

Similarly, the mobile device can be mounted on a package or unit of ESD-sensitive electronics or other material while it is being moved or stored in a manufacturing facility, or between facilities. This would provide an indication or alarm if the ESD-sensitive material were to come into some ESD-hazardous situation, such as close proximity to a charged object or person. It would also provide a record of the ESD history of the material, so that in the case of an audit or dispute about ESD-mitigated handling, there would be an electronic record of the material's exposure to ESD.

A record of historical sensor data is useful in the case of the wearable and fixed sensors, because it is a significant aid in diagnosing the source of ESD problems. For example, the timing of ESD events can be related to the presence or absence of a particular person or piece of equipment, and a model of ESD activity can be developed from the historical sensor data. For example, if an ESD alarm is generated each time an employee wearing a specific garment walks nearby, it could be concluded that the individual, or teams of individuals, is/are inadequately grounded and constitutes an ESD hazard. This historical record of ESD data can be provided as a deliverable with a piece of hardware that leaves a facility to certify that it has not been subjected to ESD events.

The hubs, to which the devices connect act as bridges to connect the device network to a remote data store and server, which may take the form of a distributed or “cloud” datacenter. This connection to the datacenter may be by means of wireless networks such as WiFi or cabled networks such as Ethernet. This type of datacenter can be connected to the internet, and can make use of spatially distributed and redundant storage media and servers to offer a reliable data storage service. Data to be transferred can be of the electrostatic sensing type, but can also include information about battery charge levels or any other relevant information from the device.

Data can be served and displayed from such a database for remote internet-connected users, typically by means of a simple remote internet interface such as a web browser running on an internet-connected computer. It is possible to process the data and serve it to the remote user in the form of charts, graphs, tables or lists, in such a way that a large number of data points can be reduced to an easily comprehensible display that highlights the features of interest for the user. For example, the number of alarm events from a particular facility over a period of time can be represented as a time-series chart, so that the trends and cycles in activity can easily be visualized and acted upon if necessary.

The wireless connectivity of the device to a mobile computing device such as a smart phone or tablet, also enables the viewing of data, and setting of device parameters such as alarm levels, using a mobile phone or tablet. Data delivered to the phone and presented by a phone application or browser application can be viewed in real time. For example, the wearer's body voltage can be displayed in real time as a graph. This enables sophisticated use of the device for detection and prevention of ESD events, by a mobile operator, on the factory floor or other environment where computer equipment is not available or practical.

Another feature of the internet connectivity of the entire network of devices is the ability to remotely change system and device level parameters such as the thresholds for local over-voltage and ESD alarm generation, as well as gains and filters on sensors. Moreover, firmware updates can be implemented as over-the-air (OTA) updates to any connected device in the network.

The devices also offer the possibility of giving spatially localized information on ESD events, so that for example ESD “hotspots”, that might be caused by undetected loss of grounding in say flooring or shelving, can be identified. This localization can be facilitated by reporting the location of each device and integrating it into a map or similar representation of the data. The fixed devices will be in known locations. The wearable or mobile device can be located in a number of ways. For example, location by means of wireless signal strength is well-known, and current wireless protocols (e.g., Bluetooth and z-wave) allow location by both strength and direction of signal propagation between wireless units. Coarse positioning can also be obtained by detecting which hub is receiving the strongest signal from a mobile unit. By these and other means, it may be possible to locate mobile units with great accuracy (typically on the order of centimeters). Moreover, data from an onboard inertial measurement unit and/or compass may identify in which direction the sensing device is pointing, to further identify induced charge and fields from external charged objects. The location data may be integrated with the ESD data for analysis by users.

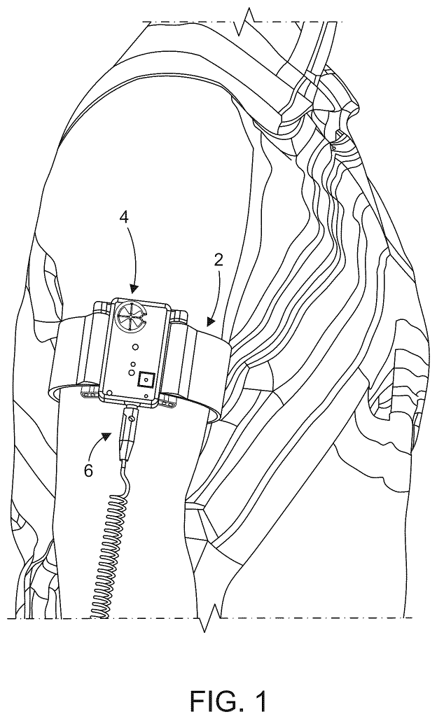

FIG. 1 shows a user wearing an embodiment of a wireless electrostatic detection device. An elastic strap 2 is used to attach the device to the user's upper arm where it is unobtrusive to the day-to-day activities of the worker. The electric field mill 4 is exposed to the environment through the enclosure, and is pointed in a direction perpendicular to the surface of the user's body so that it can measure the local surface charge density that is representative of the user's electrostatic potential. That is, the local surface charge density at the point of measure of the electric field mill 4 may be extrapolated to the entire body geometry to determine total electrostatic charge. This total charge is related to the body potential by the user's self-capacitance, in the absence of external charges. Thereby, the local E-field measurement from the device is an accurate proxy for the user's electrostatic potential, and can be used to discern problematic ESD conditions. In the case that the device is mounted on top of an insulating article of clothing, an optional grounding tether 6 connected to a common ESD wrist strap forms a grounding connection between the device's ground plane and the user's skin.

FIG. 2 shows an arrangement of a stationary or fixed sensor device 18 mounted on a workbench 14, with the sensing direction indicated by the dotted arrow 22. The device is mounted in order to measure the potential of a user 12 and protect sensitive electronics 16 on the bench. The device has a digital wireless network radio and antenna 20 by which it can communicate its measurements and status to a central hub and thereby to the Internet or the cloud. Light emitting diodes with variable intensity, or any other visual interface, can be used to indicate the detected level of charge on the user. The device 18 is also capable of generating an audible alarm sound 24 so as to warn the user 12 that they should not handle electronics because their electrostatic potential is hazardously high. The back of the bench 26 or wall may optionally be coated with conductive material to aid in localizing and directing the axis of sensitivity of the device.

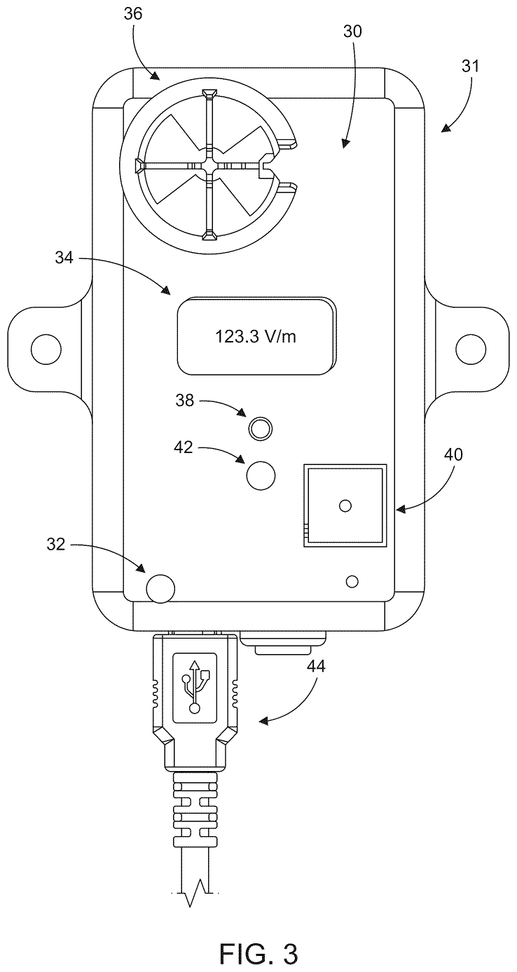

FIG. 3 shows details of a device such as the one shown in FIG. 2, though these details could apply to wearable variations. There is an electric field sensor 36 arranged to be sensitive in the desirable direction, generally perpendicular to the mounting surface 30 of the device housing 31. There may also be a proximity or distance sensor 32, using optical, ultrasonic, millimeter wave, radio or similar means, that is arranged to sense the presence and distance of people or objects in the same direction (approximately on the same axis) as the electric field sensor 36. The device may have a buzzer or speaker 40 or similar to give audible alarms, and a button or similar for user input 38. The user input 38 may serve to change the mode of operation of the device, or adjust or zero its parameters, or mute or enable alarms, or any other input that may serve to make the device more effective. There may be user feedback displays in the form of one or more LEDs 42 or an LCD or similar display 34. The device may be wired 44 in such a way that it is connected to the main building or local ground and may also have a wired power supply and/or a battery.

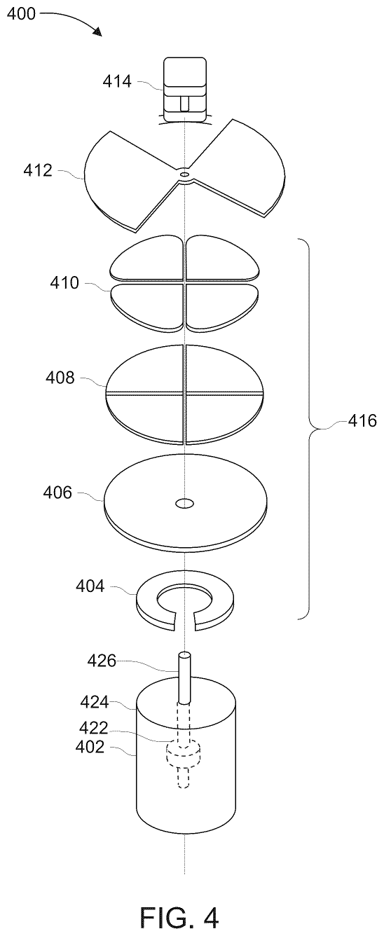

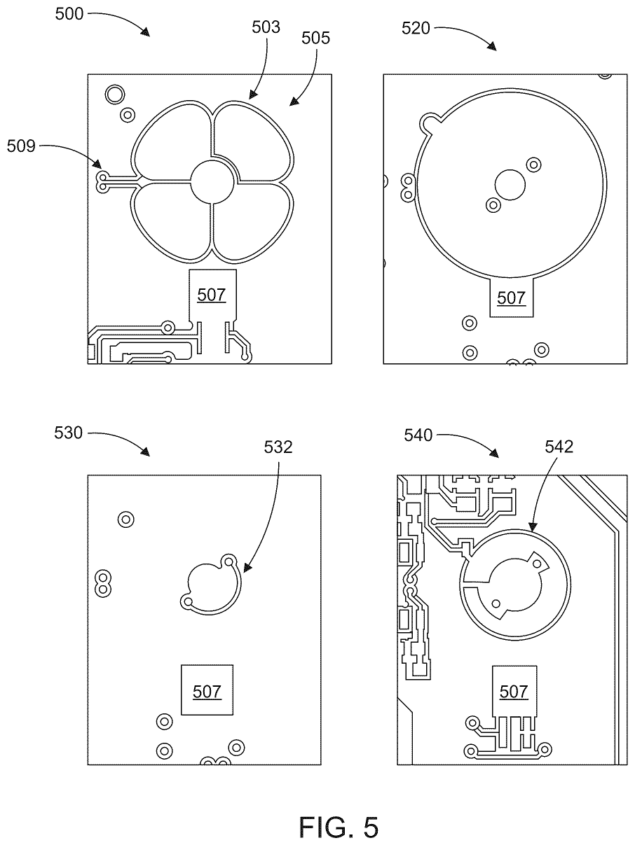

FIG. 4 shows an exploded view of the sensor structure. In some embodiments, the sensor 400 can be implemented as the electric field sensor 36 in FIG. 3. For simplicity, electrical connections to the components in FIG. 4 are not shown, but examples of such connections can be seen in FIG. 5. Apart from the motor 402, the shutter 412 that it rotates, and the photodiode 414 used to track the position of the shutter 412, the whole sensor 400 can be fabricated as conductive layers in a single PCB stack 416. There can be as many as four layers (e.g., one, two, three, or four layers), including the sense electrodes 410, calibration or null electrodes 408, a rear shield 406, and the motor connection 404. The rear shield 406 may comprise an isolated rear shield that is grounded to isolate the sense electrodes 410 from electrical signals in the PCB stack 416. Alternatively or additionally, the rear shield 406 may be driven at a controlled voltage according to a sensing algorithm. The null electrodes 408 are configured to null or calibrate the sensor 400 according to its application or environment for improved sensitivity and accuracy.

In some embodiments, one or more of the four layers in the illustrated stack 416 can be fabricated in a single layer. For instance, the sense electrodes 410 and the null electrodes 408 could be fabricated on two sides of a single PCB or could be deposited as two layers on a semiconductor with a dielectric or insulating layer between them. Charged ionic air particles may be absorbed by the sense electrodes 410 to create a current into the sensor 400. The motor connection 404 provides an electrical connection to the motor case 424 so that it can be grounded. A metal bushing 422 is internal to the motor 402 and mounted/coupled with the motor shaft 426 to electrically couple the motor 402 and the shutter 412. Precise alignment of the layers as well as the motor 402 is ensured by the monolithic nature of the PCB stack 416. Alignment can also be enhanced by fabricating two or more components of the stack 416 on a single PCB or semiconductor layer (with PCB or dielectric material between the components). Further, though the photodiode 414 is shown as a distinct component, in some instances, it may be fabricated as a monolithic component with one of the components of the stack 416. For instance, where at least one of the components of the stack 416 is fabricated on a semiconductor substrate, the photodiode 414 could be fabricated on the same substrate. The photodiode 414 can be arranged outside a radius of the stack 416 but inside the radius of the shutter 412.

FIG. 5 shows four layers of an electric field sensor fabricated in PCB. In practice these layers are superimposed (stacked) in the PCB stack, but here are shown side-by-side, for clarity. In the figure, much of the white areas represent the conductive copper layers of the PCB, and the lines may represent where the copper has been etched away to create the circuit. The PCB layers shown are the sensor electrodes on the top layer 500 (e.g., 410 in FIG. 4), a second layer 520 underneath the top layer 500 having an internal shield (e.g., 406 in FIG. 4), a third layer 530 underneath the second layer 520, and the motor electrical connections (e.g., 404 in FIG. 4) on the bottom layer 540. The motor case can be soldered or otherwise affixed directly, or via a mounting bracket, to the bottom layer 540 of the PCB, thereby ensuring solid mechanical mounting and good electrical contact in an immovable junction. In FIG. 5, it can be seen that each layer has a white square below the electrode stack. The photodetector (e.g., photodiode 414 of FIG. 4) that detects the location of the shutter is positioned or mounted within this aperture 507 in the PCB, and connects directly to the circuit as well. Although the illustration shows a photodiode that passes through all four layers, in other embodiments, a lower-profile photodiode may be implemented that can be mounted on one of the layers, and therefore the aperture 507 may only be needed in one or more of the four layers. In other embodiments, a different method for detecting the position of the shutter may be used, such as a retroreflective sensor, or a non-optical method such as an induction measurement, or a brushless DC motor with built-in position detection or control.

In the top layer 500 of the PCB, the sense electrodes (e.g., 410 in FIG. 4) are the cloverleaf structure 503 at or near the center of the layer, which provides a more sinusoidal signal, and hence less noise, than sector shapes used in the prior art. The cloverleaf structure 503 may comprise four rounded lobes that are symmetrical about the center of the structure. It can be seen that the electrodes are tightly surrounded by a conductive plane 505, which serves to reduce the possibility of contamination, as well as providing a flat reference plane, in the same plane and at the same potential as the sense electrodes, so that the electric field under measurement is perpendicular, uniform and undistorted with respect to the sense electrodes. In one embodiment, the cloverleaf structure 503 includes four cloverleaf-shaped electrodes which are connected in pairs so that each pair may be alternately covered by the rotating shutter. Alternative sense electrode structures and shapes are contemplated including, for example, three leaves, eight leaves, without beveled edges, etc. Conductive traces 509 connecting the sense electrodes to an amplifier (not shown) are also shown. The upper conductive trace 509 couples to the upper left and lower right sense electrodes 503, while the lower conductive trace 509 couples to the lower left and upper right sense electrodes 503.

The internal shield of the second layer 520 may comprise an isolated rear shield that is grounded to isolate the sense electrodes from electrical signals in the PCB. Alternatively or additionally, the internal shield may be driven at a controlled voltage according to a sensing algorithm. The optional third layer 530 may include one or more connections 532 (e.g., via PCB trace) between electrode pairs (e.g., electrically connecting the top right and bottom left electrodes in this example). In a conventional field mill, these connections are made using wires which are more exposed to electrical noise. It should be noted that the third layer 530 is optional, since a backplane electrode on the backside (not visible) of the top layer 500 could be used to connect the lower left and upper right sensor electrodes rather than the connections 532.

In the fourth or bottom layer 540, an isolated ring 542 (e.g., motor connection 404 of FIG. 4) at or near a center of the layer allows contact between the motor case (e.g., 424) and the PCB. By having a direct electrical connection between the motor and the PCB circuit, a technical benefit is provided in that the metal case of the motor may be directly connected to the shielding structures in the PCB, thereby significantly improving the shielding of the sensitive sensor electrodes from the noisy electric fields in the circuits and the motor.

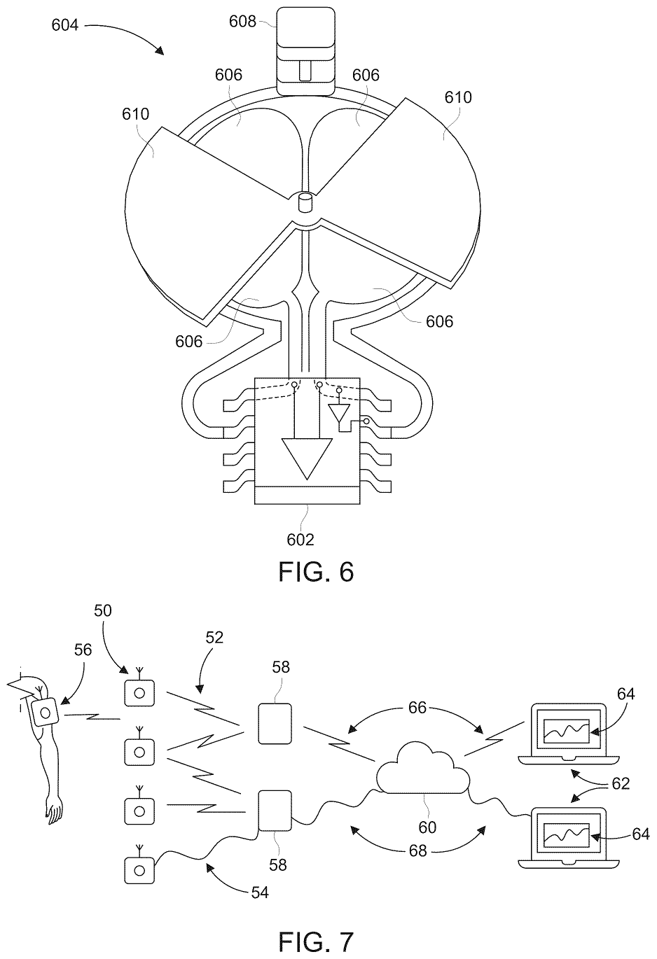

FIG. 6 shows an embodiment of a miniaturized electric field mill with bias and sensing electronics. Notably, a processor or other digital or analog circuit 602 can be connected to the electric field mill 604 so as to read a voltage from the clover-shaped sense electrode 606. A photodiode 608 can be arranged toward a periphery of the electric field mill 604 such that its beam is interrupted each time that a shutter 610 passes through the beam. A signal from the photodiode 608 can also couple into the processor or circuit 602. For clarity, other aspects of the electric field mill 604 such as the motor, calibration electrodes, rear shield, and motor connector are not shown.

The electric field mill 604 and circuit 602 provide a technical benefit of reducing noise to improve sensor measurement quality and thus accuracy in estimating body or object potential. In one embodiment, the current generated in the sensor 604 does not introduce error in the electric field measurement because only signals that are modulated by the shutter 610, and in phase with the shutter movement, are detected and translated into electric field strength. Moreover, in some embodiments, a steady ionic current is not modulated by the shutter 610. If the ionic air current were somehow to flow so that it was interrupted by the shutter 610, it would still not manifest as an erroneous electric field measurement because currents may be amplified in phase quadrature to voltage signals in the type of phase-synchronous detection created by the rotating shutter 610. Phase-synchronous detection may also have the effect of amplifying in-phase signals, and nulling quadrature signals, so the ionic current signal is nulled out and not detected.

FIG. 7 shows a data network that can support and enable the sensing devices. Both wearable devices 56 and stationary or fixed devices 50 can communicate wirelessly or by cable with hubs 58 that aggregate, process and forward the data, and may be themselves equipped with sensors such as humidity, temperature and ion density sensors. Wired 54 or wireless digital connections can also be made directly to the Internet without the use of a hub. Each device may connect with a multiplicity of hubs 58 and vice versa. The hubs 58 are further connected via wireless 66 or cabled 68 networks to the Internet and/or cloud. The hubs 58 act as bridges to transfer the information, via the Internet, to a distributed or “cloud” datacenter 60 such as has become standard for storing and serving of industrial and commercial data.

The data can then be accessed from the cloud datacenter server 60 by remote user computers 62 and the data can be presented in the form of charts 64 or other analytical representation, for easy interpretation of the immediate and historical activity and performance of the devices 50/56. Alarms (not shown) can also be generated at the remote computer 62 sites, as well as locally at the devices 50/56 and/or hubs 58. Alarms may take the form of audible tones, flashing lights, vibrations, text or graphic messages, electronic mail, or any other form that may be useful to engage the user's attention. The remote user computers 62 may also take the form of smartphones or mobile tablets, allowing the remote users to access data and receive alarms from any location and under any circumstances as necessary.

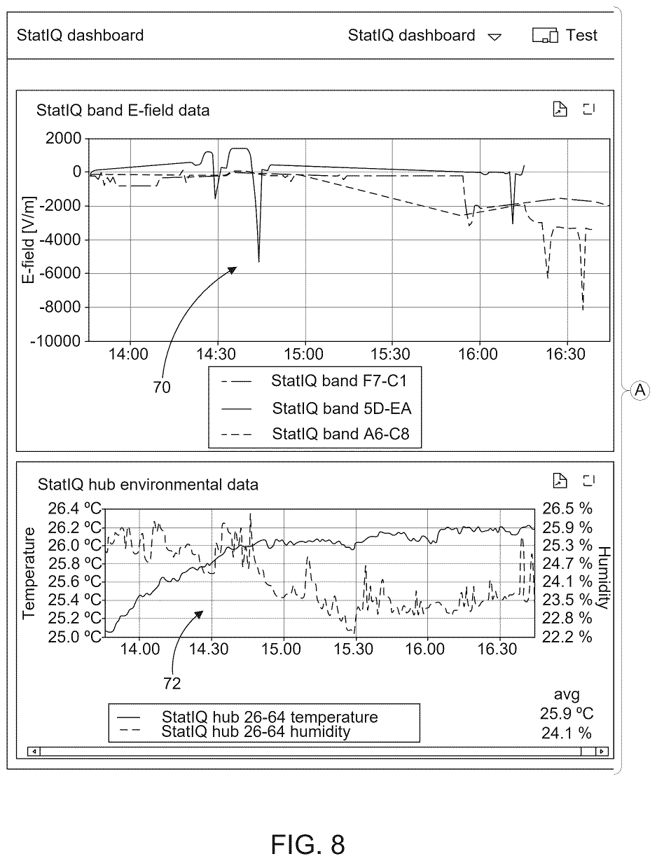

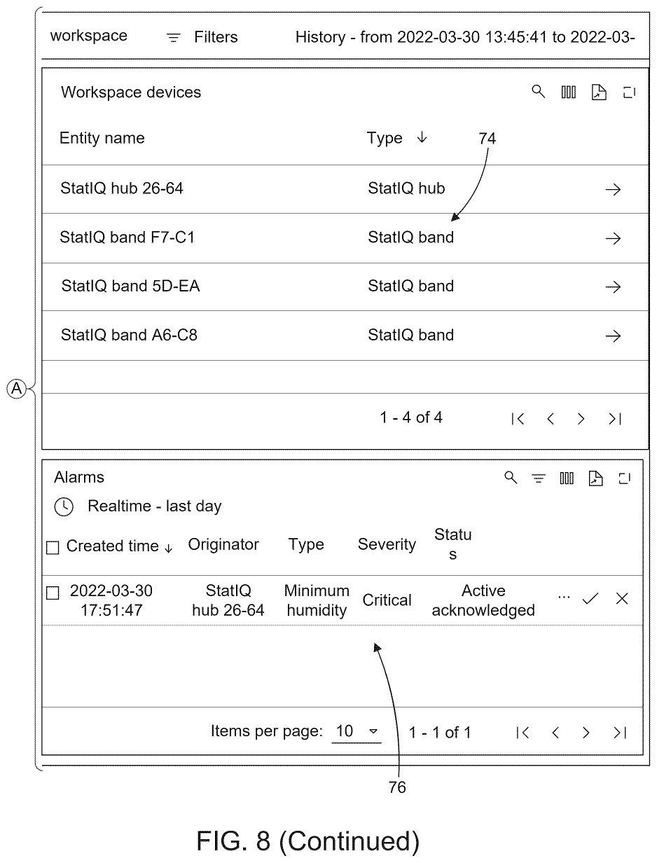

FIG. 8 shows the presentation of data for the above-mentioned sensors for a remote user in the form of a dashboard of charts and tabular data on a computer screen, as served in the form of a web page by a cloud server. The presentation includes graphical time series data from multiple devices 70, as well as graphical time series data of environmental measurements of humidity and temperature 72, as carried out by the secondary sensors on the hub or device. There is a tabular list of available devices for display 74 and a list of recent alarms generated by these devices 76, indicating thresholds that have been exceeded for both electrostatic and environmental data, or rapid changes in electric field indicating a discharge event. This gives the user a simple and easily visible representation of recent ESD activity. Should further detail be required, the user may select items on the screen by means of a computer mouse click, resulting in a pop-up window or separate dashboard that will provide further specific information on that device or feature.

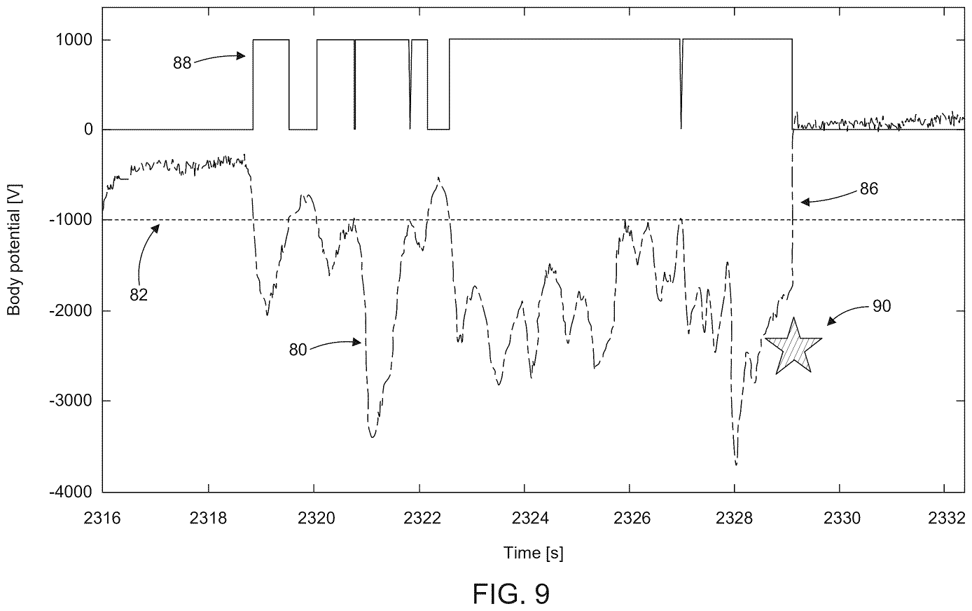

FIG. 9 shows an exemplary chart of body potential as deduced by the recorded electric field measurement from a wearable device of the type described herein. A first trace 80 or plotted line shows the voltage on a wearer walking on a non-conductive floor, and accumulating charge through triboelectric charge separation as their feet contact and leave the floor. A horizontal dashed line represents the device's negative threshold alarm 82 voltage set at, in this example, +/−1000V. A second trace 88 or plotted line shows the periods of time during which the wearer is exceeding the alarm threshold 82 and for which an alarm would be generated. After some walking around, the wearer touches a ground point and discharge occurs; this discharge event 86 may be represented by a vertical line (e.g., at approximately time 2329 in FIG. 8) of the first trace 80 and may be identified both visually and via an algorithm by the high rate of voltage change. A visual and or audible alarm 90 can also be generated by this event.

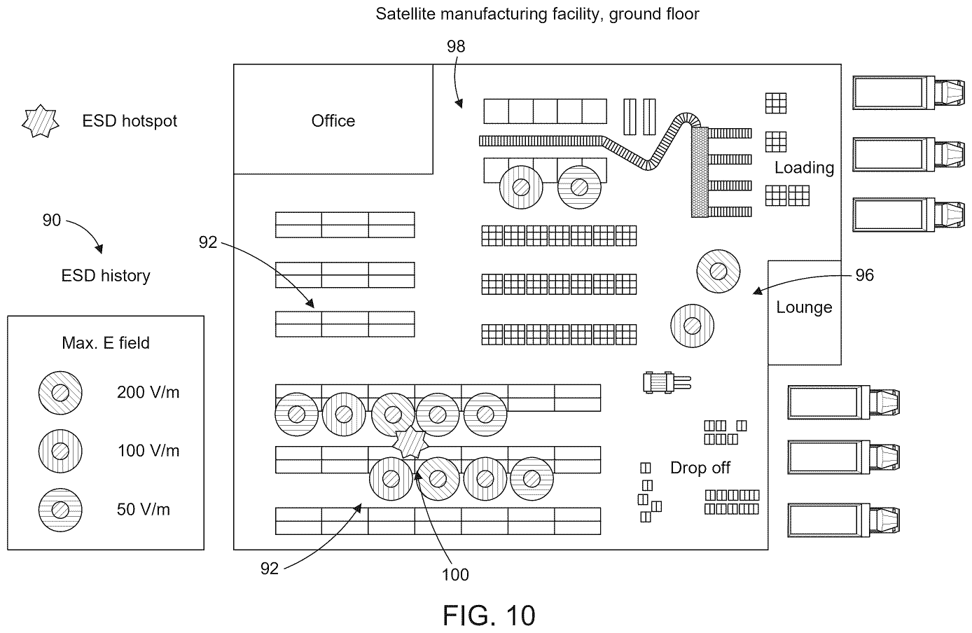

FIG. 10 shows an example of a representation of a floor map of a manufacturing facility, as it might be presented remotely by the data server described above. It shows features in the floor plan such as benches 92 and conveyors 98. The map has a scale 90 for the data of interest-in this case the highest E-field recorded by the device over a specific historical time period, and shows where the events are taking place, e.g., as measured by fixed units at benches 94 or as measured by wearable units on personnel 96. ‘ESD hotspots’ 100 can be identified in the facility where one or many ESD events are measured to have occurred.

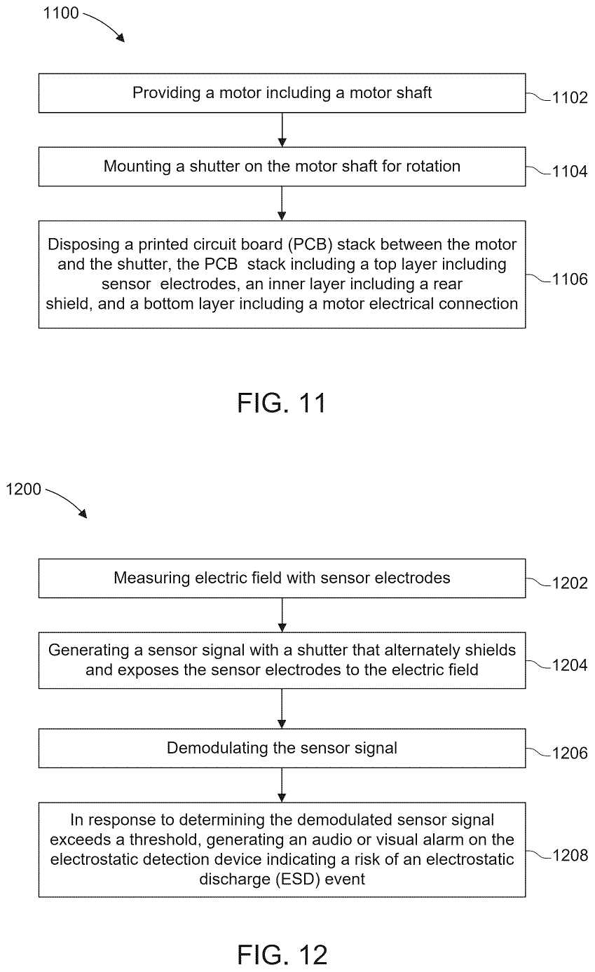

FIG. 11 illustrates a method of manufacturing an electrostatic detection device in one embodiment. The method 1100 can include providing a motor including a motor shaft (Block 1102). The method 1100 can further include mounting a shutter on the motor shaft for rotation (Block 1104). The method 1100 can further include disposing a printed circuit board (PCB) stack between the motor and the shutter, the PCB stack including a top layer including sensor electrodes, an inner layer including a rear shield, and a bottom layer including a motor electrical connection (Block 1106).

FIG. 12 illustrates a method of mitigating electrostatic discharge (ESD) events with an electrostatic detection device in one embodiment. The method 1200 can include measuring electric field with sensor electrode (Block 1202). The method 1200 can further include generating a sensor signal with a shutter that alternately shields and exposes the sensor electrodes to the electric field (Block 1204). The method 1200 can further include demodulating the sensor signal (Block 1206). The method 1200 can further include, in response to determining the demodulated sensor signal exceeds a threshold, generating an audio or visual alarm on the electrostatic detection device indicating a risk of an electrostatic discharge (ESD) event (Block 1208).

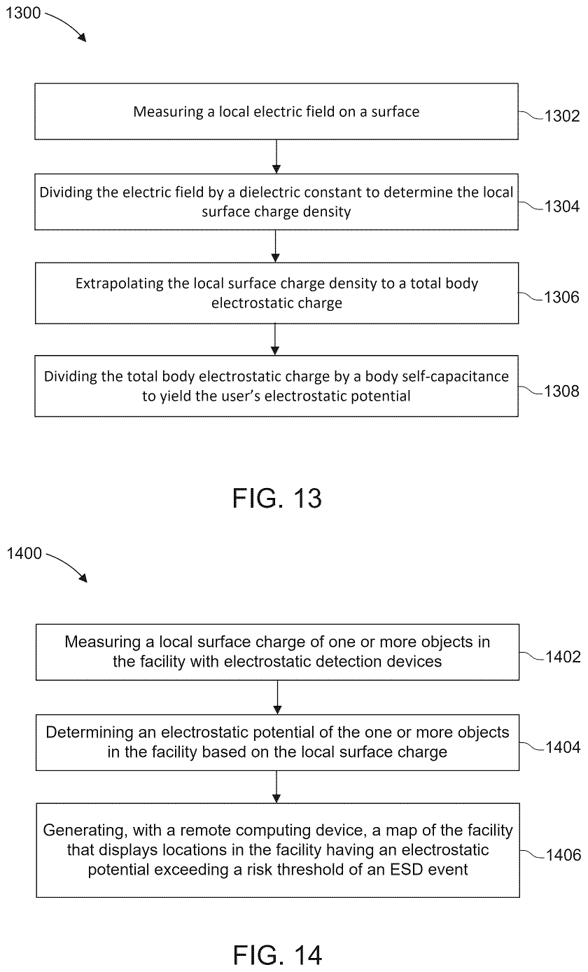

FIG. 13 illustrates a method of estimating an object or user body potential in one embodiment. The method 1300 can include measuring a local electric field on a surface (Block 1302). The method 1300 can also include dividing the electric field by a dielectric constant to determine the local surface charge density (Block 1304). The method 1300 can also include extrapolating the local surface charge density to a total body electrostatic charge (Block 1306). The method 1300 can also include dividing the total body electrostatic charge by a body self-capacitance to yield the user's electrostatic potential (Block 1308).

In some embodiments, Blocks 1302-1308 may be effectively performed with a body factor that converts an electrical field measurement to object or body potential according to: V=BF×E, where V is the object or user electrical static potential (e.g., measured in volts (V), BF is the body factor in meters (m), and E is the measured electric field measured in volts per meter (V/m). Thus, an ESD mitigation device or system may estimate an object or body potential by multiplying the local electric field on a surface by the body factor. In one embodiment, the body factor is derived empirically by comparing the measurement of a device's E-field measurements to a wired voltage measurement using a surface voltmeter. The device may be programmed to use a body factor for a person of average height and weight (e.g., a body factor between 0.2655 m to 0.3245 m). The body factor may vary by less than ten percent for most body types. Adjustments can thus be made device/system programming instructions according to the height and weight of the user to further increase voltage measurement accuracy. For example, a look-up table or algorithms that relate the body factor to user height and weight may be stored and executed. This data can be derived empirically or using electrostatics finite element analysis programs.

FIG. 14 illustrates a method of mitigating electrostatic discharge (ESD) events in a facility in one embodiment. The method 1400 can include measuring a local surface charge of one or more objects in the facility with electrostatic detection devices (Block 1402). The method 1400 can further include determining an electrostatic potential of the one or more objects in the facility based on the local surface charge (Block 1404). The method 1400 can further include generating, with a remote computing device, a map of the facility that displays locations in the facility having an electrostatic potential exceeding a risk threshold of an ESD event (Block 1406).

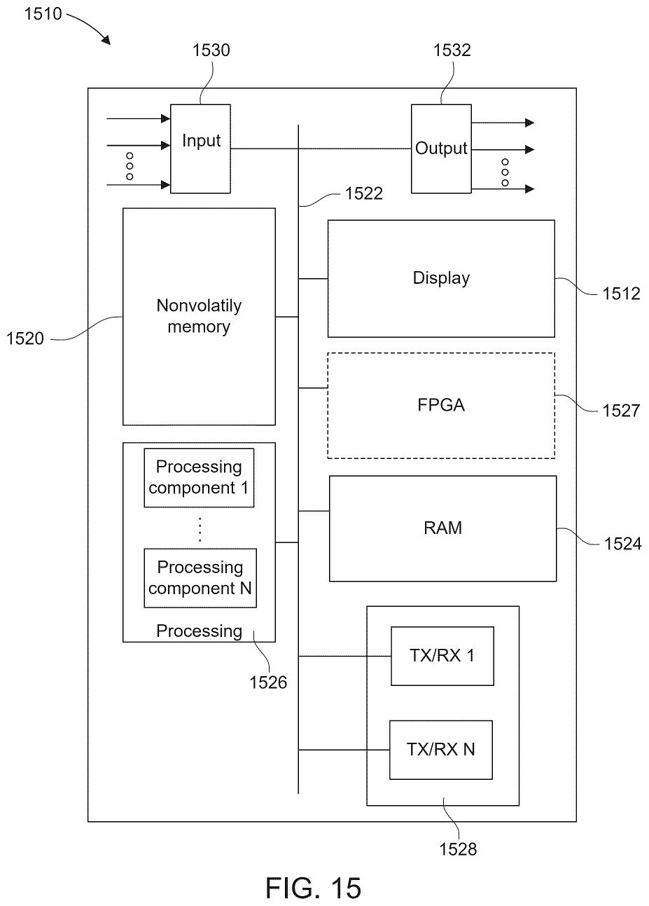

The methods described in connection with the embodiments disclosed herein may be embodied directly in hardware, in processor-executable code encoded in a non-transitory tangible processor readable storage medium, or in a combination of the two. Referring to FIG. 15 for example, shown is a block diagram 1410 depicting physical components that may be utilized to realize, for example, the circuit 602, according to an exemplary embodiment. As shown, in this embodiment a display portion 1412 and nonvolatile memory 1420 are coupled to a bus 1422 that is also coupled to random access memory (“RAM”) 1424, a processing portion (which includes N processing components) 1426, an optional field programmable gate array (FPGA) 1427, and a transceiver component 1428 that includes N transceivers, which may be wireless. Although the components depicted in FIG. 15 represent physical components, FIG. 15 is not intended to be a detailed hardware diagram; thus, many of the components depicted in FIG. 15 may be realized by common constructs or distributed among additional physical components. Moreover, it is contemplated that other existing and yet-to-be developed physical components and architectures may be utilized to implement the functional components described with reference to FIG. 15.

This display portion 1412 generally operates to provide a user interface for a user, and in several implementations, the display is realized by a touchscreen display. In general, the nonvolatile memory 1420 is non-transitory memory that functions to store (e.g., persistently store) data and processor-executable code (including executable code that is associated with effectuating the methods described herein). In some embodiments for example, the nonvolatile memory 1420 includes bootloader code, operating system code, file system code, and non-transitory processor-executable code to facilitate the execution of a method described herein.

In many implementations, the nonvolatile memory 1420 is realized by flash memory (e.g., NAND or ONENAND memory), but it is contemplated that other memory types may be utilized as well. Although it may be possible to execute the code from the nonvolatile memory 1420, the executable code in the nonvolatile memory is typically loaded into RAM 1424 and executed by one or more of the N processing components in the processing portion 1426.

The N processing components in connection with RAM 1424 generally operate to execute the instructions stored in nonvolatile memory 1420 to enable electrostatic charge mitigation via ion discharge. For example, non-transitory, processor-executable code to effectuate the methods described with reference to FIGS. 12 and 13 may be persistently stored in nonvolatile memory 1420 and executed by the N processing components in connection with RAM 1424. As one of ordinarily skill in the art will appreciate, the processing portion 1426 may include a video processor, digital signal processor (DSP), micro-controller, graphics processing unit (GPU), or other hardware processing components or combinations of hardware and software processing components (e.g., an FPGA or an FPGA including digital logic processing portions).

In addition, or in the alternative, the processing portion 1426 may be configured to effectuate one or more aspects of the methodologies described herein (e.g., the methods described with reference to FIGS. 12 and 13). For example, non-transitory processor readable instructions may be stored in the nonvolatile memory 1420 or in RAM 1424 and when executed on the processing portion 1426, cause the processing portion 1426 to perform a method for mitigating ESD events. Alternatively, non-transitory FPGA-configuration-instructions may be persistently stored in nonvolatile memory 1420 and accessed by the processing portion 1426 (e.g., during boot up) to configure the hardware-configurable portions of the processing portion 1426 to effectuate the functions of the circuit 602 or processor(s).

The input component 1430 operates to receive signals (e.g., the electrostatic charge sensed at the sensor electrodes) that are indicative of one or more aspects of the charge buildup on the user's body. The signals received at the input component may include, for example, a voltage, current, or digital signal, depending on the type of sensor or sensing section used. The output component generally operates to provide one or more analog or digital signals for ESD mitigation such as alarms or warnings generated for the device itself or other devices in communication therewith.

The depicted transceiver component 1428 includes N transceiver chains, which may be used for communicating with external devices via wireless or wireline networks. Each of the N transceiver chains may represent a transceiver associated with a particular communication scheme (e.g., WiFi, Ethernet, Profibus, etc.). The use of wireless communication enables the devices disclosed here to be located in space through their communication with fixed wireless base stations of known locality (for example, if the wireless communication technology used is the Bluetooth Low Energy 5.1 standard, location services are an integral part of the communication protocol). This enables the devices to be used to map out, within a factory floor or manufacturing facility, those areas where there are “hot spots” or high occurrence of ESD events or even high density of charge. This is performed by communicating from the device to a central processor the location of the device, together with information about the accumulation of charge on the wearer.

Some portions are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is a self-consistent sequence of operations or similar processing leading to a desired result. In this context, operations or processing involves physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The terms and expressions employed herein are used as terms and expressions of description and not of limitation, and there is no intention, in the use of such terms and expressions, of excluding any equivalents of the features shown and described or portions thereof. Each of the various elements disclosed herein may be achieved in a variety of manners. This disclosure should be understood to encompass each such variation, be it a variation of an embodiment of any apparatus embodiment, a method or process embodiment, or even merely a variation of any element of these. Particularly, it should be understood that the words for each element may be expressed by equivalent apparatus terms or method terms-even if only the function or result is the same. Such equivalent, broader, or even more generic terms should be considered to be encompassed in the description of each element or action. Such terms can be substituted where desired to make explicit the implicitly broad coverage to which this invention is entitled.

As but one example, it should be understood that all action may be expressed as a means for taking that action or as an element which causes that action. Similarly, each physical element disclosed should be understood to encompass a disclosure of the action which that physical element facilitates. Regarding this last aspect, by way of example only, the disclosure of a “protrusion” should be understood to encompass disclosure of the act of “protruding”-whether explicitly discussed or not-and, conversely, were there only disclosure of the act of “protruding”, such a disclosure should be understood to encompass disclosure of a “protrusion”. Such changes and alternative terms are to be understood to be explicitly included in the description.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

As used herein, the recitation of “at least one of A, B and C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

1. An electrostatic detection device, comprising:
a motor including a motor shaft;
a shutter mounted on the motor shaft for rotation; and
a printed circuit board (PCB) stack disposed between the motor and the shutter, the PCB stack including:
a top layer including sensor electrodes;
an inner layer including a rear shield; and
a bottom layer including a motor electrical connection, wherein the PCB stack comprises a monolithic structure including multiple layers of conductor-coated fiberglass sheet.

2. (canceled)

3. The electrostatic detection device of claim 11, further comprising;
an aperture extending through one or more of the multiple layers; and
a photodiode situated in the aperture.

4. The electrostatic detection device of claim 3, further comprising:
a circuit electrically coupled with the sensor electrodes via the PCB stack, the circuit configured to receive a sensor signal from the sensor electrodes, to receive a shutter position signal from the photodiode, to demodulate the sensor signal based on the shutter position signal to give a demodulated sensor signal, and in response to determining the demodulated sensor signal exceeds a threshold, to generate an audio or visual alarm on the electrostatic detection device indicating a risk of an electrostatic discharge (ESD) event.

5. The electrostatic detection device of claim 1, wherein:
the sense electrodes comprise a cloverleaf structure in the top layer.

6. The electrostatic detection device of claim 5, wherein:
the cloverleaf structure is surrounded by a conductive plane in the top layer; and
at least one of the cloverleaf pairs is electrically coupled via traces in another PCB layer disposed between the inner layer and the bottom layer.

7. The electrostatic detection device of claim 1, further comprising:
a metal bushing mounted on the motor shaft, the metal bushing configured to electrically couple the motor and the shutter.

8. The electrostatic detection device of claim 1, wherein;
the bottom layer of the PCB stack includes an isolated ring to electrically couple the motor with the rear shield.

9. The electrostatic detection device of claim 1, wherein:
the PCB stack further includes a layer of calibration electrodes disposed between the sense electrodes and the inner layer.

10. An electrostatic detection device, comprising:
sensor electrodes configured to measure electric field;
a shutter configured to alternately shield and expose the sensor electrodes to the electric field to generate a sensor signal; and
a processor configured to demodulate the sensor signal to generate a demodulated sensor signal, and in response to determining the demodulated sensor signal exceeds a threshold, to generate an audio or visual alarm on the electrostatic detection device indicating a risk of an electrostatic discharge (ESD) event, wherein
the electrostatic detection device is configured to be attached to a fixed object,
the sensor electrodes are configured to measure a local surface charge of a user in proximity to the fixed object,
the processor is configured to determine an electrostatic potential of the body of the user based on the local surface charge, and to generate the audio or visual alarm based on a comparison of the electrostatic potential to the threshold.

11-13. (canceled)

14. The electrostatic detection device of claim 10, further comprising:
a proximity sensor configured to detect a distance from the electric detection device to a user;
wherein the processor is configured to determine the electrostatic potential of the body of the user based at least in part on the distance.

15. The electrostatic detection device of claim 10, further comprising;
a directional sensor configured to detect a direction of the user with respect to the electric detection device;
wherein the processor is configured to determine the electrostatic potential of the body of the user based at least in part on the direction.

16. (canceled)

17. The electrostatic detection device of claim 10, further comprising:
a wireless transceiver configured to transmit data of the risk of the ESD event to a remote computing device for tracking ESD events in a facility.

18. The electrostatic detection device of claim 10, wherein:
the processor is configured to direct a motor to rotate the shutter at a blade pass frequency that is an integer multiple of an electrical supply frequency of a facility, and to direct programming instructions to demodulate the signal produced from the sensor electrodes at the electrical supply frequency,

19. The electrostatic detection device of claim 18, wherein:
the programming instructions compensate the demodulated signal based on a phase error between a shutter signal and an electrode signal.

20. The electrostatic detection device of claim 10, further comprising:
a motor configured to rotate the shutter; and
a printed circuit board (PCB) stack disposed between the motor and the shutter, the PCB stack including:
a top layer including the sensor electrodes;
an inner layer including a rear shield; and
a bottom layer including a motor electrical connection.

21. A system for mitigating electrostatic discharge (ESD) events in a facility, comprising:
a plurality of electrostatic detection devices attached to one or more users, workbenches. or ESD-sensitive packages in the facility, each electrostatic detection device configured to measure a local surface charge of one or more users, workbenches. or ESD-sensitive packages in the facility, to determine an electrostatic potential of the one or more users, workbenches, or ESD-sensitive packages in the facility, and to transmit data of the electrostatic potential of the one or more users, workbenches, or ESD-sensitive packages in the facility;
one or more hubs disposed in the facility configured to forward the data of the electrostatic potential of the one or more users, workbenches, or ESD-sensitive packages in the facility; and
a remote computing device configured to receive the data of the electrostatic potential of the one or more users, workbenches, or ESD-sensitive packages in the facility, and to generate a map of the facility that displays locations in the facility having or that have had an electrostatic potential exceeding a risk threshold of an ESD event.

22. The system of claim 21, wherein:
the remote computing device is configured to record the electrostatic potential of the one or more users, workbenches, or ESD-sensitive packages of the facility over time, and to maintain the record of the electrostatic potential of the one or more users, workbenches, or ESD-sensitive packages of the facility to validate ESD mitigation performance of the facility.

23. The system of claim 21, wherein:
the remote computing device configured to receive location data of the one or more users, workbenches, or ESD-sensitive packages in the facility, and to correlate the location data with the data of the electrostatic potential for reporting of spatially localized ESD mitigation performance of the facility.

24. (canceled)

25. The system of claim 21, wherein:
the remote computing device includes a user interface configured to receive user input to adjust the risk threshold of an electrostatic detection device.

26. The system of claim 21, wherein:
the remote computing device is configured to generate an alarm indicating one or more users, workbenches, or ESD-sensitive packages in the facility exceed the risk threshold.

27. The system of claim 26, wherein:
the remote computing device is configured to display the alarm on the map of the facility.

28. The system of claim 21, further comprising:
one or more environmental sensors disposed in the facility configured to detect one or more of humidity, temperature, and air ion density;
wherein the remote computing device is configured to process data of the one or more environmental sensors to determine ESD conditions of the facility.

29. The system of claim 21, wherein:
the remote computing device is configured to generate a graph of the electrostatic potential of the one or more users, workbenches, or ESD-sensitive packages in the facility with respect to time.

30-58. (canceled)
